(19) United States
(12) Patent Application Publication
(10) Pub. No.: US 2024/0200891 A1
(43) Pub. Date: Jun. 20, 2024

(54) COOLING DEVICE

(71) Applicant: Nidec Corporation, Kyoto (JP)

(72) Inventors: Yoshihisa KITAMURA, Kyoto (JP); Toshihiko TOKESHI, Kyoto (JP); Takehito TAMAOKA, Kyoto (JP)

(21) Appl. No.: 18/537,976

(22) Filed: Dec. 13, 2023

(30) Foreign Application Priority Data
Dec. 14, 2022 (JP) 2022-199464

(51) Int. Cl. F28F 9/26

(52) U.S. Cl. CPC F28F 9/262

(57) ABSTRACT

A cooling device includes a pump assembly to circulate a refrigerant, a tank to accommodate the refrigerant, and a heat exchanger to cool the refrigerant circulating in the tank and the pump assembly. The pump assembly and the tank are connected via a first flow path having a tubular shape. An end portion positioned on a vertically upper side of the tank is above an end portion on a vertically upper side of the pump assembly. One end portion of the first flow path is connected to a surface facing a vertically lower portion of the tank.

### CROSS-REFERENCE TO RELATED APPLICATIONS

The present application claims priority under 35 U.S.C. § 119 to Japanese Patent Application No. 2022-199464, filed on Dec. 14, 2022, the entire contents of which are hereby incorporated herein by reference.

### 1. FIELD OF THE INVENTION

The present disclosure relates to cooling devices.

### 2. BACKGROUND

In a conventional liquid cooling box, a bottom plate of a housing main body is installed with a condenser, a micro pump, and a liquid storage tank. The condenser, the micro pump, and the liquid storage tank are connected to one another via an internal flow path. A working medium circulates inside the condenser, the micro pump, the liquid storage tank, and the internal flow path.

In the conventional liquid cooling box, the height of the condenser and the micro pump from the bottom plate is higher than the height of the top portion of the liquid storage tank from the bottom plate. Therefore, gas other than the working medium such as air is easily mixed into the condenser and the micro pump. In particular, when gas is mixed into the micro pump, the mixed gas is conveyed to the condenser together with the working medium by the micro pump, and the cooling efficiency of the condenser is easily reduced.

### SUMMARY

An example embodiment of a cooling device of the present disclosure includes a pump assembly, a tank, and a heat exchanger. The pump assembly circulates a refrigerant. The tank accommodates the refrigerant. The heat exchanger cools the refrigerant circulating in the tank and the pump assembly. The pump assembly and the tank are connected via a first flow path having a tubular shape. An end portion positioned on a vertically upper side of the tank is positioned above an end portion positioned on a vertically upper side of the pump assembly. One end portion of the first flow path is connected to a surface opposing vertically downward of the tank.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic perspective view of a cooling device of an example embodiment of the present invention.

FIG. 2 is a schematic perspective view of a circulation unit 10 in a cooling device of an example embodiment of the present invention.

FIG. 3 is a schematic view of a cooling device of an example embodiment of the present invention as viewed from a first direction one side.

FIG. 4 is a schematic view of a cooling device of an example embodiment of the present invention as viewed from a second-direction other side.

FIG. 5 is a schematic view of a cooling device of an example embodiment of the present invention as viewed from a third direction one side.

### DETAILED DESCRIPTION

Hereinafter, example embodiments of the present disclosure will be described with reference to the drawings. In the drawings, the same or corresponding parts are denoted by the same reference signs and description thereof will not be repeated. In the present description, a first direction X, a second direction Y, and a third direction Z that are orthogonal to one another are described as appropriate for ease of understanding. One side in the first direction X is described as a first-direction one side X1, and the other side in the first direction X is described as a first-direction other side X2. One side in the second direction Y is described as a second-direction one side Y1, and the other side of the second direction Y is described as a second-direction other side Y2. One side in the third direction Z is described as a third-direction one side Z1, and the other side in the third direction Z is described as third-direction other side 22. However, the direction is defined merely for convenience of description, and the orientation during use of the exemplary cooling device of the present disclosure is not limited unless it is necessary to define the horizontal direction and the vertical direction in particular. In the present description, an “orthogonal direction” includes a substantially orthogonal direction.

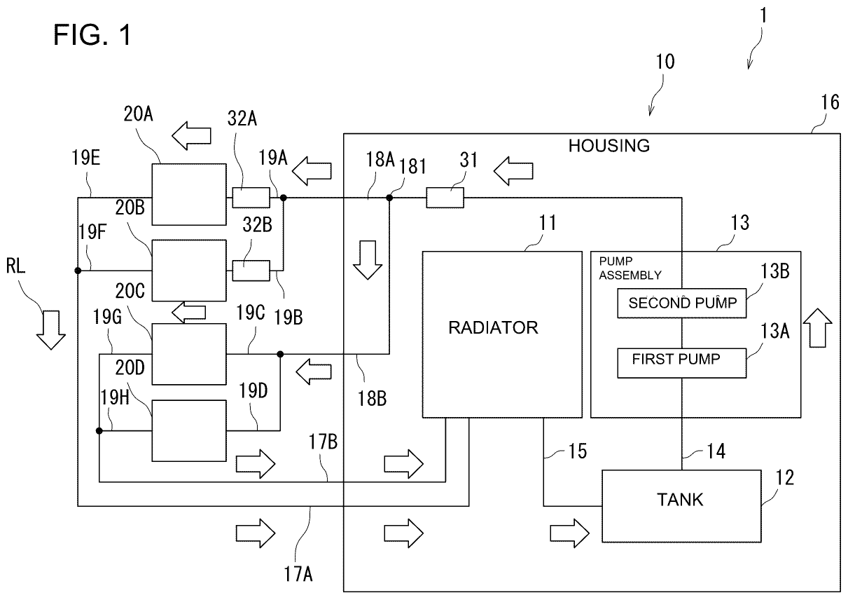

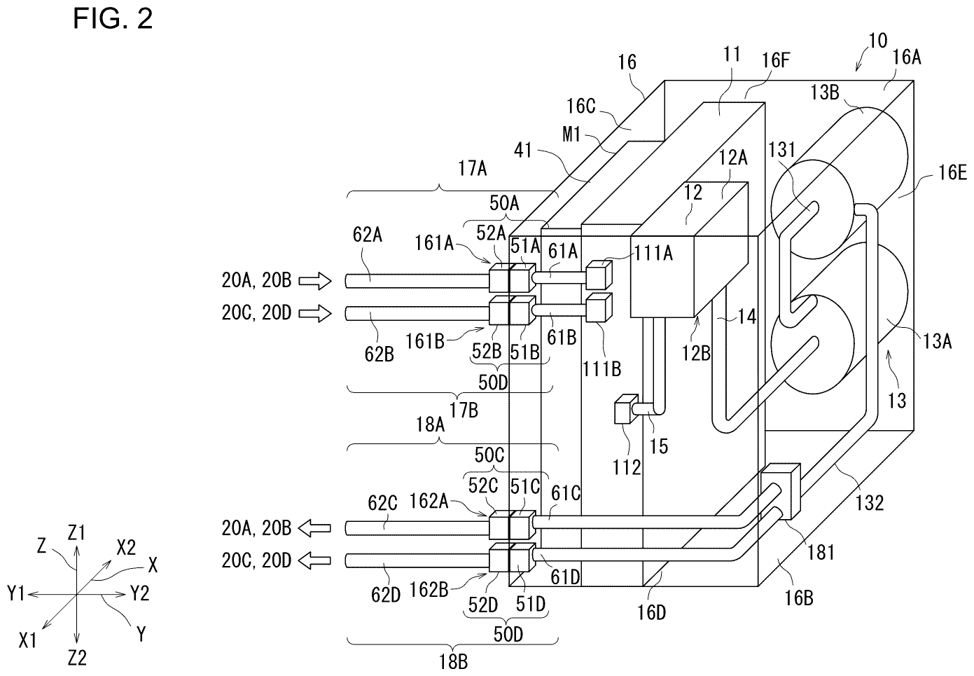

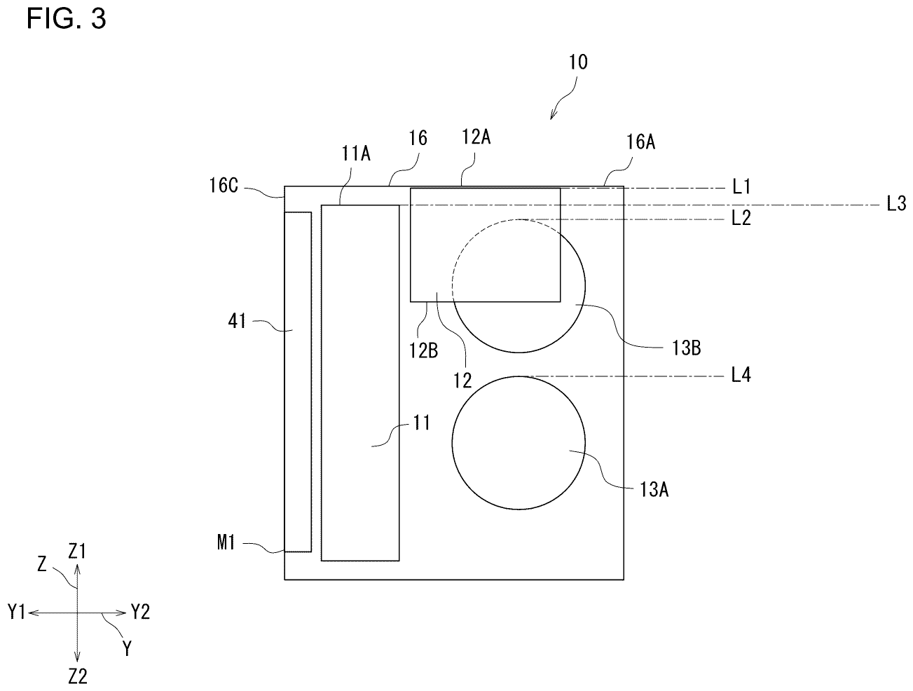

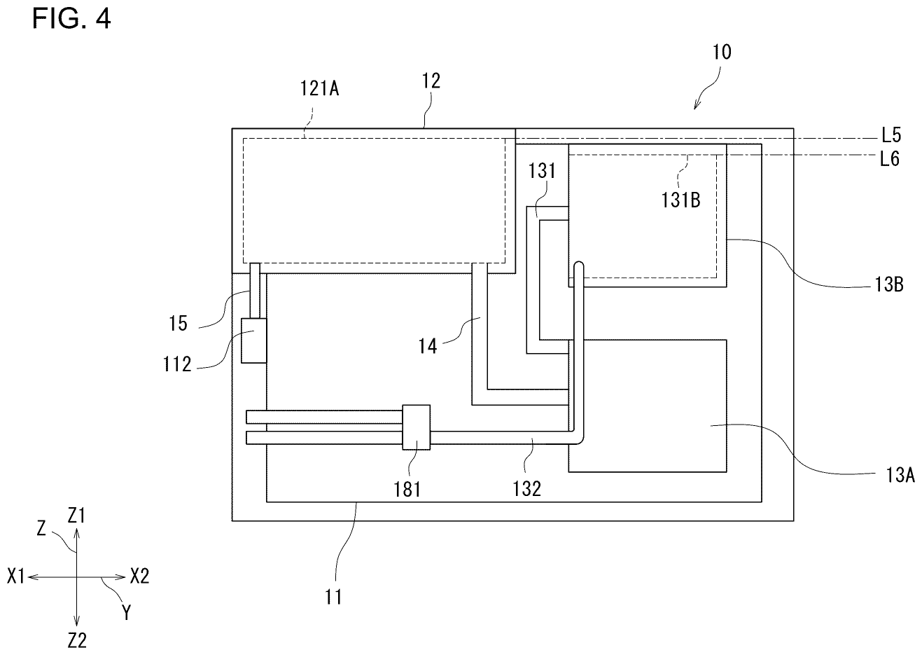

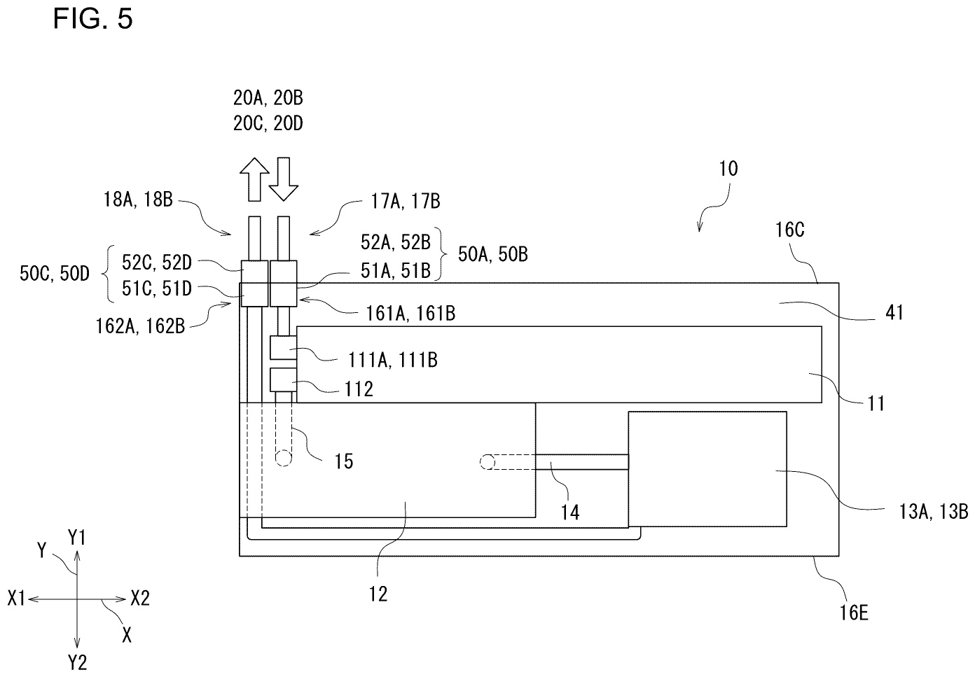

With reference to FIGS. 1 to 5, a cooling device 1 of an example embodiment will be described. FIG. 1 is a schematic perspective view of the cooling device 1. FIG. 2 is a schematic perspective view of the circulation unit 10 in the cooling device 1 of the example embodiment. FIG. 3 is a schematic view of the cooling device 1 of the example embodiment as viewed from the first direction one side X1. FIG. 4 is a schematic view of the cooling device 1 of the example embodiment as viewed from the second-direction other side Y2. FIG. 5 is a schematic view of the cooling device 1 of the example embodiment as viewed from the third direction one side Z1. FIGS. 3 to 5 illustrate some configurations omitted to facilitate understanding of the drawings.

As illustrated in FIGS. 1 and 2, the cooling device 1 includes the circulation unit 10, a plurality of cooling assemblies 20, a first guide portion 17, and a second guide portion 18. The circulation unit 10 and the plurality of cooling assemblies 20 are connected to each other via the first guide portion 17 and the second guide portion 18 as flow paths through which a refrigerant RL passes. In the example illustrated in FIG. 1, the cooling device 1 includes four cooling assemblies 20A, 20B, 20C, and 20D. The four cooling assemblies 20A, 20B, 20C, and 20D include cold plates on which heat generating components not illustrated are disposed. The refrigerant RL is, for example, liquid or gas. When the refrigerant RL passes through the four cooling assemblies 20A, 20B, 20C, and 20D, heat exchange is performed with the heat generating component not illustrated via the cold plates, the heat generating component is cooled, and the temperature of the refrigerant RL increases. The heat generating component is, for example, an electronic device such as a central processing unit (CPU). The heat generating component is not limited to an electronic device.

The refrigerant RL circulates between the circulation unit 10 and the plurality of cooling assemblies 20. Specifically, the refrigerant RL is guided from the circulation unit 10 to the cooling assembly 20 by the second guide portion 18, passes through the cooling assembly 20, and returns to the circulation unit 10 by the first guide portion 17. In FIG. 1, the circulation direction of the refrigerant RL in the cooling device 1 is indicated by an arrow. The circulation unit 10 includes a radiator 11, a tank 12, a pump assembly 13, a housing 16, and a cooling fan 41. The housing 16 accommodates the radiator 11, the tank 12, the pump assembly 13, the cooling fan 41, and a plurality of flow paths connecting any two of the radiator 11, the tank 12, and the pump assembly 13. The pump assembly 13 is driven to circulate the refrigerant RL in the cooling device 1. That is, the refrigerant RL returns from the pump assembly 13 in the circulation unit 10 to the pump assembly 13 via the second guide portion 18, the plurality of cooling assemblies 20, the first guide portion 17, the radiator 11, and the tank 12 in this order. That is, the second guide portion 18 guides the refrigerant RL from the pump assembly 13 accommodated inside the housing 16 of the circulation unit 10 to the plurality of cooling assemblies 20 provided outside the housing 16. The first guide portion 17 guides the refrigerant RL from the plurality of cooling assemblies 20 provided outside the housing 16 to the radiator 11 accommodated inside the housing 16 of the circulation unit 10. The radiator 11 is an example of a heat exchanger that cools the refrigerant RL by allowing the refrigerant RL to pass through inside thereof. The circulation unit 10 may include, as a heat exchanger other than the radiator 11, a plate-type heat exchanger that cools the refrigerant RL by heat exchange with cooling water, for example.

The housing 16 includes a first surface 16A facing the third-direction one side Z1 of the third direction Z indicating the vertical direction, a second surface 16B facing the third-direction other side 22 of the third direction Z, and four connection surfaces 16C, 16D, 16E, and 16F connecting the first surface 16A and the second surface 16B. For example, the connection surface 16C and the connection surface 16E extend along the first direction X. The connection surface 16D and the connection surface 16F extend along the second direction Y.

For example, the connection surface 16 has an opening M1. The cooling fan 41 is disposed along the opening M1 inside the housing 16. That is, the cooling fan 41 is positioned at the end on the second direction one side Y1 inside the housing 16. This enables the cooling fan 41 to suck air outside the housing 16 through the opening M1 and send the air to the inside of the housing 16. That is, the cooling fan 41 blows air toward the inside of the housing 16.

Next, the arrangement of the pump assembly 13 and the tank 12 will be described with reference to FIGS. 2 to 4. As illustrated in FIGS. 2 to 4, the pump assembly 13 includes a first pump 13A and a second pump 13B. When at least one of the first pump 13A and the second pump 13B is driven, the refrigerant RL is sent in one direction and circulates in the cooling device 1. The first pump 13A and the second pump 13B are connected in series to each other via a flow path 131 having a tubular shape. Specifically, the first pump 13A sends the refrigerant RL to the second pump 13B via the flow path 131. The first pump 13A and the second pump 13B are positioned on the first-direction other side X2 relative to the tank 12.

The second pump 13B sends the refrigerant RL sent from the first pump 13A to the plurality of cooling assemblies 20 via a flow path 132 having a tubular shape and the second guide portion 18. Specifically, one end portion of the flow path 132 is connected to the second pump 13B. The other end portion of the flow path 132 is connected to a branch portion 181. Second guide portions 18A and 18B, which are the second guide portion 18, are further connected to the branch portion 181. The branch portion 181 branches the refrigerant RL passed through the flow path 132 into the second guide portions 18A and 18B to pass therethrough. Details of the second guide portion 18A and the second guide portion 18B and the other connection destination of the second guide portion 18A and the second guide portion 18B will be described later.

As illustrated in FIG. 2, the first pump 13A and the second pump 13B have substantially columnar shapes extending along the first direction X. In the first pump 13A and the second pump 13B, an impeller rotates about a rotation axis extending along the first direction X, whereby the refrigerant RL is sent in one direction. That is, the first pump 13A and the second pump 13B are centrifugal pumps that send, to the second direction Y or the third direction Z with respect to the rotation axis by the centrifugal force of the rotation of the impeller, the refrigerant RL flowed through the flow path extending in the first direction X connected to the position of each rotation axis. The second pump 13B is positioned on the third direction one side Z1 relative to the first pump 13A.

The shapes of the first pump 13A and the second pump 13B are not limited to the substantially columnar shapes. The flow path 131 connects a side surface portion of the first pump 13A and the position of the rotation axis of the second pump 13B, but the positions to which both end portions of the flow path 131 are connected are not limited to the above. By vertically arranging the first pump 13A and the second pump 13B, it is possible to arrange a plurality of pumps inside the housing 16. As a result, for example, even when one pump is stopped, the other pump is driven so that the use of the cooling device 1 can be continued.

The tank 12 accommodates the refrigerant RL. As illustrated in FIG. 2, the tank 12 has a substantially cuboid shape. Specifically, the tank 12 includes an upper surface 12A facing the third-direction one side Z1, a lower surface 12B facing the third-direction other side 22, and four side surfaces connecting the upper surface 12A and the lower surface 12B. That is, when circulating through the cooling device 1, the refrigerant RL temporarily remains inside the tank 12 surrounded by the upper surface 12A, the lower surface 12B, and the four side surfaces.

The circulation unit 10 includes a first flow path 14 having a tubular shape as a flow path connecting the tank 12 and the first pump 13. By driving of the pump assembly 13 including the first pump 13A, the refrigerant RL accommodated in the tank 12 passes through the first flow path 14 and is sucked into the pump assembly 13. One end portion of the first flow path 14 is connected to the lower surface 12B of the tank 12. The other end portion of the first flow path 14 is connected to the position of the rotation axis of the first pump 13.

The first pump 13 is disposed on the third-direction other side Z2 relative to the lower surface 12B of the tank 12. More specifically, as illustrated in FIG. 3, a position L4 of the end portion positioned on the third-direction one side Z1 of the first pump 13A is positioned on the third-direction other side Z2 relative to the position of the lower surface 12B of the tank 12.

As illustrated in FIG. 3, in the third direction Z, a position L1 of the upper surface 12A, which is the end portion on the third direction one side Z1 of the tank 12, is positioned on the third direction one side Z1 relative to a position L2 of the end portion on the third direction one side Z1 of the second pump 13B. More specifically, as illustrated in FIG. 4, a position L5 of a top surface 121A of an inner wall of the tank 12 is positioned on the third direction one side Z1 relative to a position L6 of a top surface 131B of an inner wall of the second pump 13B.

Due to this, gas such as air having a specific gravity lighter than that of the refrigerant RL is likely to accumulate above the tank 12 positioned at a position higher than the second pump 13B in the cooling device 1. Furthermore, since the first flow path 14 through which the refrigerant RL flows out of the tank 12 is provided on the lower surface 12B of the tank 12, the gas accumulated above the tank 12 hardly flows out to the first flow path 14. Therefore, gas other than the refrigerant RL is less likely to be mixed into the pump assembly 13. As a result, circulation of gas in the cooling device 1 is suppressed. Therefore, the refrigerant RL is efficiently supplied to the radiator 11 in the cooling device, and a decrease in cooling efficiency in the radiator 11 can be suppressed.

Since the first pump 13A is positioned vertically below the lower surface 12B of the tank 12, mixing of gas into the first pump 13A can be further suppressed as compared with the second pump 13B. Therefore, the use of the first pump 13A can be easily continued as compared with the second pump 13B.

Furthermore, by disposing the first pump 13A immediately after the tank 12, even when gas is mixed in the refrigerant, the gas mixed in the tank 12 gathers, and thus the gas can be suppressed from entering the first pump 13A.

Next, the radiator 11 will be described with reference to FIGS. 2 to 5. The refrigerant RL passed through the radiator 11 is sucked into the tank 12 by the drive of the pump assembly 13. As illustrated in FIGS. 2 and 3, the radiator 11 is disposed on the second-direction other side Y2 relative to the cooling fan 41. The radiator 11 is disposed on the second direction one side Y1 relative to the tank 12. That is, the radiator 11 is positioned between the cooling fan 41 and the tank 12 in the second direction Y. The radiator 11 includes a plurality of refrigerant pipes not illustrated through inside of which the refrigerant RL passes, inflow portions 111A and 111B that cause the refrigerant RL to flow into the plurality of refrigerant pipes, and an outflow portion 112 that causes the refrigerant RL to flow out of the plurality of refrigerant pipes. The plurality of refrigerant pipes extends to reciprocate along the first direction X. One end portion of each of the plurality of refrigerant pipes is connected to the inflow portion 111. The other end portion of each of the plurality of refrigerant pipes is connected to the outflow portion 112. For example, the inflow portion 111 and the outflow portion 112 are disposed on the first direction one side X1 with respect to the plurality of refrigerant pipes.

Specifically, the plurality of refrigerant pipes extends to the first-direction other side X2 with respect to the inflow portion 111, are folded back to the first-direction one side X1 while being curved toward the second-direction other side Y2 at the end portion on the first-direction other side X2 of the radiator 11, then extend to the first-direction one side X1, and are connected to the outflow portion 112. In other words, the refrigerant RL passes from the first-direction one side X1 to the first-direction other side X2 on the second-direction one side Y1 among the plurality of refrigerant pipes, and the refrigerant RL passes from the first-direction other side X2 to the first-direction one side X1 on the second-direction other side Y2 among the plurality of refrigerant pipes. The inflow portion 111 is at the same position as the second-direction one side Y1 among the plurality of refrigerant pipes in the second direction Y, and the outflow portion 112 is at the same position as the second-direction other side Y2 among the plurality of refrigerant pipes in the second direction Y. By arranging the plurality of refrigerant pipes while causing the radiator 11 to reciprocate in this manner, the distance between the plurality of refrigerant pipes becomes long, and the heat of the refrigerant RL passing through the plurality of refrigerant pipes is easily dissipated. That is, the refrigerant RL having a higher temperature than that on the second-direction other side Y2 among the plurality of refrigerant pipes passes through the second-direction one side Y1 among the plurality of refrigerant pipes.

In the example illustrated in FIG. 2, the inflow portion 111A and the inflow portion 111B are arranged side by side in the third direction Z at the same position in the second direction Y. Each of the inflow portion 111A and the inflow portion 111B distributes the refrigerant RL passed through the tank 12 and the pump assembly 13 and circulated in the cooling device 1 to the plurality of refrigerant pipes and allows the refrigerant RL to flow thereinto. Hereinafter, each of the inflow portion 111A and the inflow portion 111B may be simply described as the inflow portion 111.

The outflow portion 112 is disposed on the first direction one side X1 with respect to the plurality of refrigerant pipes. The outflow portion 112 is disposed to overlap at least a part of the tank 12 in the second direction Y. The outflow portion 112 causes the refrigerant RL passed through the plurality of refrigerant pipes to join and causes the refrigerant RL to flow out of the plurality of refrigerant pipes.

The plurality of refrigerant pipes are disposed at intervals in the third direction Z. A plurality of fins is disposed around each of the plurality of refrigerant pipes. A part of each of the plurality of fins is in contact with the refrigerant pipe. More specifically, the fin and the refrigerant pipe are joined by welding or the like. The fins absorb heat of the refrigerant pipes and the refrigerant RL and radiate the heat to the outside air, thereby lowering the temperature of the refrigerant RL. Furthermore, by blowing air from the cooling fan 41 to the plurality of refrigerant pipes and the plurality of fins, the heat of the refrigerant pipes and the refrigerant RL is easily radiated to the outside air. In particular, when the cooling fan 41 is provided on the second direction one side Y1 relative to the radiator 11, the air blown from the cooling fan 41 easily hits the second direction one side Y1 through which the higher-temperature refrigerant RL passes among the plurality of refrigerant pipes, and the cooling efficiency of the refrigerant RL by the radiator 11 is improved. Extension of the plurality of fins in a bellows shape in the second direction Y increases the area where the air blown from the cooling fan 41 comes into contact with the plurality of fins, and improves the cooling efficiency of the refrigerant RL by the radiator 11.

The circulation unit 10 includes a second flow path 15 having a tubular shape as a flow path connecting the tank 12 and the radiator 11. One end portion of the second flow path 15 is connected to the lower surface 12B of the tank 12. The other end portion of the second flow path 15 is connected to the outflow portion 112. As illustrated in FIG. 2, in the third direction Z, the outflow portion 112 is positioned on the third-direction other side Z2 relative to the lower surface 12B of the tank 12. That is, the other end portion of the second flow path 15 is positioned on the third-direction other side Z2 relative to the lower surface 12B of the tank 12. Therefore, the second flow path 15 has a substantially L shape that extends from the outflow portion 112 toward the second-direction other side Y2 along the second direction Y, then bends toward the third-direction one side Z1, and extends toward the third-direction one side Z1 along the third direction Z.

As illustrated in FIG. 3, the position L1 of the upper surface 12A of the tank 12 in the third direction Z is positioned on the third direction one side Z1 relative to the position L3 of the end portion on the third direction one side Z1 of the radiator 11.

Since the upper surface 12A of the tank 12 is positioned vertically above the upper end portion of the radiator 11, gas is more likely to accumulate above the tank 12 relative to the radiator 11. More specifically, when the upper surface 12A of the tank 12 is positioned vertically above the refrigerant pipe on the third direction one side Z1 among the plurality of refrigerant pipes of the radiator 11, gas is less likely to accumulate in the refrigerant pipe on the most third direction one side Z1 among the plurality of refrigerant pipes. Furthermore, since the second flow path 15 through which the refrigerant RL flowing into the tank 12 passes is connected to the lower surface 12B of the tank 12, even if gas is mixed into the tank 12 through the second flow path 15, the refrigerant RL hardly flows out from the first flow path 14.

The inflow portions 111A and 111B, the outflow portion 112, and the second flow path 15 can be arranged in a substantially linear shape by forming the second flow path 15 in a substantially L shape. As a result, in the housing 16, the length of the flow path in the second direction Y can be shortened, the cooling device 1 can be made compact, the flow path resistance in the cooling device 1 is reduced, and the power consumption of the pump assembly 13 can be reduced.

In the present example embodiment, the inflow portion 11A of the radiator 111 is connected to a first guide portion 17A, which is the first guide portion 17. The inflow portion 11B of the radiator 111 is connected to a first guide portion 17B, which is the first guide portion 17.

Next, the first guide portion 17 and the second guide portion 18 will be described with reference to FIGS. 2 and 5. The first guide portion 17 includes at least two flow path tubes 61A and 62A through which the refrigerant RL passes, and a connection portion 50A connecting the flow path tube 61A and the flow path tube 62A to each other. The connection portion 50A includes a first connector 51A and a second connector 52A fitted to each other. For example, the connection portion 50 is a pair of connectors in which the first connector 51A has a male terminal shape and the second connector 52A has a female terminal shape. The flow path tube 61A is, for example, a pipe, and has one end portion connected to the first connector 51A and the other end portion connected to the inflow portion 111A of the radiator 11. The flow path tube 62A is, for example, a pipe, and has one end portion connected to the second connector 52A and the other end portion connected to the cooling assemblies 20A and 20B. The pipe is made of resin or metal. The resin pipe is inexpensive and has excellent flexibility. On the other hand, the metal pipe can suppress transpiration of the refrigerant RL.

Similarly to the first guide portion 17A, the first guide portion 17B includes at least two flow path tubes 61B and 62B through which the refrigerant RL passes, and a connection portion 50B connecting the flow path tube 61B and the flow path tube 62B to each other. The connection portion 50B includes a first connector 51B and a second connector 52B fitted to each other. The flow path tube 61B is, for example, a pipe, and has one end portion connected to the first connector 51B and the other end portion connected to the inflow portion 111B of the radiator 11. The flow path tube 62B is, for example, a pipe, and has one end portion connected to the second connector 52B and the other end portion connected to the cooling assemblies 20C and 20D.

As illustrated in FIGS. 2 and 5, the housing 16 of the circulation unit 10 includes a first holding portion 161A holding the first connector 51A in the first guide portion 17A and a first holding portion 161B holding the first connector 51B in the first guide portion 17B. The first holding portions 161A and 161B are disposed on the connection surface 16C, which is a wall surface on the second direction one side Y1 of the housing 16. The first holding portions 161A and 161B are ring-shaped packings or gaskets, for example. Thus, since the first connectors 51A and 51B are fixed to the connection surface 16C by the first holding portions 161A and 161B, the radiator 11 is positioned on the second-direction other side Y2 relative to the first holding portions 161A and 161B. Furthermore, the position of the first holding portion 161A on the connection surface 16C overlaps the inflow portion 111A in the second direction Y and the third direction Z. The position of the first holding portion 161B on the connection surface 16C overlaps the inflow portion 111B in the second direction Y and the third direction Z.

On the other hand, as illustrated in FIGS. 2 and 5, the second guide portion 18A includes at least two flow path tubes 61C and 62C through which the refrigerant RL passes, and a connection portion 50C connecting the flow path tube 61C and the flow path tube 62C to each other. The connection portion 50C includes a first connector 51C and a second connector 52C fitted to each other. The flow path tube 61C is, for example, a pipe, and has one end portion connected to the first connector 51C and the other end portion connected to the branch portion 181. The flow path tube 62C is, for example, a pipe, and has one end portion connected to the second connector 52C and the other end portion connected to the cooling assemblies 20A and 20B.

The second guide portion 18B includes at least two flow path tubes 61D and 62D through which the refrigerant RL passes, and a connection portion 50D connecting the flow path tube 61D and the flow path tube 62D to each other. The connection portion 50D includes a first connector 51D and a second connector 52D fitted to each other. The flow path tube 61D is, for example, a pipe, and has one end portion connected to the first connector 51D and the other end portion connected to the branch portion 181. The flow path tube 62D is, for example, a pipe, and has one end portion connected to the second connector 52D and the other end portion connected to the cooling assemblies 20C and 20D.

As illustrated in FIGS. 2 and 5, the housing 16 of the circulation unit 10 includes a second holding portion 162A holding the first connector 51C in the second guide portion 18A and a second holding portion 162B holding the first connector 51D in the second guide portion 18B. The second holding portions 162A and 162B are disposed on the connection surface 16C, which is a wall surface on the second direction one side Y1 of the housing 16. The second holding portions 162A and 162B are members similar to the first holding portions 161A and 161B. That is, the radiator 11 is positioned on the second-direction other side Y2 relative to the second holding portions 162A and 162B.

By fixing and holding the connector 50 of the first guide portion 17 and the second guide portion 18 to the housing 16, it is possible to stably dispose the flow path inside the housing 16.

The end portion on the first direction one side X1 of the tank 12 is positioned on the first direction one side X1 relative to the inflow portions 111A and 111B and the outflow portion 112 of the radiator 11, and a part of the tank 12 overlaps the inflow portions 111A and 111B and the outflow portion 112 in the second direction Y, whereby the length of the second flow path 15 can be further shortened.

By connecting the flow path tubes inside and outside the housing 16 by the connector 50 whose one side is fixed to the housing 16, it becomes easy to insert and remove the flow path tubes in the cooling device 1.

The first holding portions 161A and 161B and the second holding portions 162A and 162B may hold parts other than the first connector in each of the first guide portions 17A and 17B and the second guide portions 18A and 18B. In this case, the first guide portions 17A and 17B and the second guide portions 18A and 18B need not be provided with the connection portions 50A to 50D.

By fixing and holding a part of the first guide portion 17 and a part of the second guide portion 18 to the housing 16, it is possible to stably dispose the flow path inside the housing 16.

Next, connection between the circulation unit 10 and the cooling assemblies 20A, 20B, 20C, and 20D via the first guide portion 17 and the second guide portion 18 will be described with reference to FIG. 1.

The second guide portion 18 includes branch paths 19A, 19B, 19C, and 19D branching based on the number of the cooling assemblies 20. The branch paths 19A, 19B, 19C, and 19D are flow path tubes such as pipes, for example. Specifically, the flow path tube 62C of the second guide portion 18A illustrated in FIG. 2 branches into the branch path 19A and the branch path 19B. The branch path 19A is connected to the cooling assembly 20A, and divides and guides a part of the refrigerant RL passing through the flow path tube 62C to the cooling assembly 20A. The branch path 19B is connected to the cooling assembly 20B, and divides and guides a part of the refrigerant RL passing through the flow path tube 62C to the cooling assembly 20B. The flow path tube 62D of the second guide portion 18B illustrated in FIG. 2 branches into the branch path 19C and the branch path 19D. The branch path 19C is connected to the cooling assembly 20C, and divides and guides a part of the refrigerant RL passing through the flow path tube 62D to the cooling assembly 20C. The branch path 19D is connected to the cooling assembly 20D, and divides and guides a part of the refrigerant RL passing through the flow path tube 62D to the cooling assembly 20D.

As illustrated in FIG. 1, the first guide portion 17 includes branch paths 19E, 19F, 19G, and 19H branching based on the number of the cooling assemblies 20. The branch paths 19E, 19F, 19G, and 19H are flow path tubes such as pipes, for example. Specifically, the flow path tube 62A of the first guide portion 17A illustrated in FIG. 2 branches into the branch path 19E and the branch path 19F. The branch path 19E is connected to the cooling assembly 20A, and the refrigerant RL passed through the cooling assembly 20A passes through the branch path 19E. The branch path 19F is connected to the cooling assembly 20B, and the refrigerant RL passed through the cooling assembly 20B passes through the branch path 19F. The flow path tube 62B of the first guide portion 17B illustrated in FIG. 2 branches into the branch path 19G and the branch path 19H. The branch path 19G is connected to the cooling assembly 20C, and the refrigerant RL passed through the cooling assembly 20C passes through the branch path19G. The branch path 19H is connected to the cooling assembly 20D, and the refrigerant RL passed through the cooling assembly 20D passes through the branch path 19H. The flow path tube 62A merges the refrigerant RL passed through the branch path 19E and the branch path 19F and guides it to the inflow portion 111A of the radiator 11 illustrated in FIG. 2. The flow path tube 62B merges the refrigerant RL passed through the branch path 19G and the branch path 19H and guides it to the inflow portion 111B of the radiator 11 illustrated in FIG. 2.

Next, measurement of a state of the refrigerant RL in the cooling device 1 will be described with reference to FIG. 1. The cooling device 1 includes a measurement device 31, a measurement device 32A, and a measurement device 32B. The measurement device 31, the measurement device 32A, and the measurement device 32B are sensor devices that measure the state of the refrigerant RL. As an example, the measurement device 31, the measurement device 32A, and the measurement device 32B are a thermometer, a pressure gauge, a flow meter, and the like. The measurement device 31, the measurement device 32A, and the measurement device 32B measure the same items.

The measurement device 31 is provided in the flow path tube 61C of the second guide portion 18 inside the housing 16 illustrated in FIG. 2. The measurement device 31 measures the state of the refrigerant RL passing through the flow path tube 61C. The measurement device 31 is an example of a first measurement assembly.

The measurement device 32A is provided in the branch path 19A illustrated in FIG. 1. The measurement device 31 measures the state of the refrigerant RL passing through the branch path 19A. The measurement device 32B is provided in the branch path 19B illustrated in FIG. 1. The measurement device 32B measures the state of the refrigerant RL passing through the branch path 19B. The measurement device 32A and the measurement device 32B are examples of a second measurement assembly.

For example, each of the measurement device 31, the measurement device 32A, and the measurement device 32B can transmit a measurement result to an external device. The external device may be a device provided outside the cooling device 1 such as a personal computer (PC) or a device provided inside the cooling device 1 such as a central processing unit (CPU) that controls the cooling device 1 not illustrated. The external device performs arithmetic processing on the measurement results transmitted from each of the measurement device 31, the measurement device 32A, and the measurement device 32B, and determines abnormality of the cooling device 1 on the basis of the arithmetic results.

By measuring the state of the refrigerant RL before and after the branch of the flow path tube 61 in this manner, it becomes easy to grasp the state of each cooling assembly 20 and the state of the circulation unit 10. As a result, for example, when the cooling device 1 is determined to be abnormal, it becomes easy to identify whether the cause of the abnormality is in the cooling assembly 20 or the circulation unit 10.

Note that the measurement device 31 may be provided in the flow path tube 61D of the second guide portion 18 other than the flow path tube 61C. In this case, the measurement device 32A and the measurement device 32B are provided in the branch path 19C and the branch path 19D, respectively. The measurement device 31, the measurement device 32A, and the measurement device 32B may be provided in the first guide portion 17A or the first guide portion 17B.

In the present example embodiment, the cooling device 1 includes the set of the first guide portion 17A and the second guide portion 18A and the set of the first guide portion 17B and the second guide portion 18B, but may include only one of the sets.

In the present example embodiment, the circulation route of the refrigerant RL is not limited to the above, and for example, the radiator 11 may be disposed after the pump assembly 13, or the pump assembly 13 may be disposed before the tank 12.

The example embodiment of the present disclosure has been described above with reference to the drawings (FIGS. 1 to 5). However, the present disclosure is not limited to the above example embodiment, and can be implemented in various modes without departing from the gist of the present disclosure. The plurality of constituent elements disclosed in the above example embodiment can be appropriately modified. For example, a certain constituent element of all constituent elements illustrated in a certain example embodiment may be added to a constituent element of another example embodiment, or some constituent elements of all constituent elements illustrated in a certain example embodiment may be removed from the example embodiment.

The drawings schematically illustrate each constituent element mainly in order to facilitate understanding of the disclosure, and the thickness, length, number, interval, and the like of the illustrated constituent elements may be different from the actual ones for convenience of creation of the drawings. The configuration of each constituent element illustrated in the above example embodiment is an example and is not particularly limited, and it goes without saying that various modifications can be made without substantially departing from the effects of the present disclosure.

The present technology can have the following configurations.

(1) A cooling device in which a refrigerant circulates, the cooling device including a pump assembly to circulate a refrigerant; a tank to accommodate the refrigerant; and a heat exchanger to cool the refrigerant circulating in the tank and the pump assembly, in which the pump assembly and the tank are connected via a first flow path having a tubular shape, an end portion positioned on a vertically upper side of the tank is positioned above an end portion positioned on a vertically upper side of the pump assembly, and one end portion of the first flow path is connected to a surface opposing a vertically lower side of the tank.

(2) The cooling device of (1), further including: a second flow path having a tubular shape and connecting the tank and the heat exchanger, in which an end portion positioned on a vertically upper side of the tank is positioned vertically above an end portion positioned on a vertically upper side of the heat exchanger, one end portion of the second flow path is connected to a surface opposing a vertically lower side of the tank, and another end portion of the second flow path is positioned on a vertically lower side relative to the one end portion of the second flow path.

(3) The cooling device of (1) or (2), in which the pump assembly includes a first pump and a second pump connected in series to each other, and an end portion positioned on a vertically upper side of the first pump is positioned on a vertically lower side relative to a surface opposing a vertically lower side of the tank.

(4) The cooling device of (3), in which the second pump is positioned on an upper side relative to the first pump, and another end portion of the first flow path is connected to the first pump.

(5) The cooling device of any of (2) to (4), in which the heat exchanger includes: a plurality of refrigerant pipes through which the refrigerant is able to pass, an inflow portion to cause the refrigerant to flow into the plurality of refrigerant pipes, and an outflow portion to cause the refrigerant to flow out of the plurality of refrigerant pipes, the plurality of refrigerant pipes extends along a first direction perpendicular to a vertical direction, in the heat exchanger, the inflow portion and the outflow portion are located on one side in a first direction with respect to the plurality of refrigerant pipes, the outflow portion is connected to the second flow path, and a portion of the second flow path extends along a second direction perpendicular to the vertical direction and the first direction.

(6) The cooling device of (5), further including: a housing accommodating the pump assembly, the tank, and the heat exchanger; a first guide portion to guide the refrigerant from an outside of the housing to an inside of the housing; and a second guide portion to guide the refrigerant from the inside of the housing to the outside of the housing, in which the housing includes: a first holding portion to hold a portion of the first guide portion, and a second holding portion to hold a portion of the second guide portion.

(7) The cooling device of (6), in which the first holding portion and the second holding portion are located on a wall surface on a second-direction one side of the housing, the heat exchanger is positioned on a second-direction other side relative to the first holding portion and the second holding portion, the tank is positioned on a second-direction other side relative to the heat exchanger, and at least a portion of the tank overlaps the outflow portion of the heat exchanger in the second direction.

(8) The cooling device of (6) or (7), in which each of the first guide portion and the second guide portion includes: two flow path tubes through which the refrigerant is able to pass, and a connection portion connecting the two flow path tubes to each other, the connection portion includes a first connector and a second connector fitted to each other, the first connector is connected to one flow path tube of the two flow path tubes, the second connector is connected to an other flow path tube of the two flow path tubes, the first holding portion holds the first connector of the first guide portion, and the second holding portion holds the first connector of the second guide portion.

(9) The cooling device of any of (6) to (8), further including: a plurality of cooling assemblies in each of which a heat generating component is included; and a first measurement assembly to measure a state of the refrigerant passing through a flow path inside the housing, in which the second guide portion includes a plurality of branch paths branching based on a number of the plurality of cooling assemblies, each of the plurality of branch paths is connected to each of the plurality of cooling assemblies to guide the refrigerant to the cooling assemblies, and the plurality of branch paths each include a second measurement assembly to measure a state of the refrigerant passing through the plurality of respective branch paths.

Example embodiments of the present disclosure can be used in the field of cooling devices.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device in which a refrigerant circulates, the cooling device comprising:
a pump assembly to circulate a refrigerant;
a tank to accommodate the refrigerant; and
a heat exchanger to cool the refrigerant circulating in the tank and the pump assembly; wherein
the pump assembly and the tank are connected via a first flow path having a tubular shape;
an end portion positioned on a vertically upper side of the tank is positioned above an end portion positioned on a vertically upper side of the pump assembly; and
one end portion of the first flow path is connected to a surface facing a vertically lower portion of the tank.

2. The cooling device according to claim 1, further comprising:
a second flow path having a tubular shape and connecting the tank and the heat exchanger; wherein
an end portion positioned on a vertically upper side of the tank is positioned vertically above an end portion positioned on a vertically upper side of the heat exchanger;
one end portion of the second flow path is connected to a surface opposing a vertically lower side of the tank; and
another end portion of the second flow path is positioned on a vertically lower side relative to the one end portion of the second flow path.

3. The cooling device according to claim 1, wherein
the pump assembly includes a first pump and a second pump connected in series to each other; and
an end portion positioned on a vertically upper side of the first pump is positioned on a vertically lower side relative to a surface opposing a vertically lower side of the tank.

4. The cooling device according to claim 3, wherein
the second pump is positioned on an upper side relative to the first pump; and
another end portion of the first flow path is connected to the first pump.

5. The cooling device according to claim 2, wherein
the heat exchanger includes:
a plurality of refrigerant pipes through which the refrigerant is able to pass;
an inflow portion to cause the refrigerant to flow into the plurality of refrigerant pipes; and
an outflow portion to cause the refrigerant to flow out of the plurality of refrigerant pipes;
the plurality of refrigerant pipes extends along a first direction perpendicular to a vertical direction;
in the heat exchanger, the inflow portion and the outflow portion are located on one side in a first direction with respect to the plurality of refrigerant pipes;
the outflow portion is connected to the second flow path; and
a portion of the second flow path extends along a second direction perpendicular to the vertical direction and the first direction.

6. The cooling device according to claim 5, further comprising:
a housing accommodating the pump assembly, the tank, and the heat exchanger;
a first guide portion to guide the refrigerant from an outside of the housing to an inside of the housing; and
a second guide portion to guide the refrigerant from the inside of the housing to the outside of the housing; wherein the housing includes:
a first holding portion to hold a portion of the first guide portion; and
a second holding portion to hold a portion of the second guide portion.

7. The cooling device according to claim 6, wherein
the first holding portion and the second holding portion are located on a wall surface on a second-direction one side of the housing;
the heat exchanger is positioned on a second-direction other side relative to the first holding portion and the second holding portion;
the tank is positioned on a second-direction other side relative to the heat exchanger; and
at least a portion of the tank overlaps the outflow portion of the heat exchanger in the second direction.

8. The cooling device according to claim 6, wherein
each of the first guide portion and the second guide portion includes:
two flow path tubes through which the refrigerant is able to pass; and
a connection portion connecting the two flow path tubes to each other;
the connection portion includes a first connector and a second connector fitted to each other;
the first connector is connected to one flow path tube of the two flow path tubes;
the second connector is connected to an other flow path tube of the two flow path tubes;
the first holding portion holds the first connector of the first guide portion; and
the second holding portion holds the first connector of the second guide portion.

9. The cooling device according to claim 6, further comprising:
a plurality of cooling assemblies in each of which a heat generating component is included; and
a first measurement assembly to measure a state of the refrigerant passing through a flow path inside the housing; wherein
the second guide portion includes a plurality of branch paths branching based on a number of the plurality of cooling assemblies;
each of the plurality of branch paths is connected to each of the plurality of cooling assemblies to guide the refrigerant to the cooling assemblies; and
the plurality of branch paths each include a second measurement assembly to measure a state of the refrigerant passing through the plurality of respective branch paths.
